(19) United States
(12) Patent Application Publication
(10) Pub. No.: US 2010/0073766 A1
(43) Pub. Date: Mar. 25, 2010

(54) MICROSCOPE SLIDE TESTING AND IDENTIFICATION ASSEMBLY

(76) Inventor: Lee H. Angros, Bethany, OK (US)

Correspondence Address: DUNLAP CODDING, P.C., PO BOX 16370, OKLAHOMA CITY, OK, 73113, US

(21) Appl. No.: 12/604,168

(22) Filed: Oct. 22, 2009

Related U.S. Application Data
(63) Continuation-in-part of application No. 11/585,448, filed on Oct. 24, 2006, now abandoned.
Application No. 11/585,448 is a continuation-in-part of application No. 11/895,501, filed on Aug. 25, 2007.
(60) Provisional application No. 60/730,285, filed on Oct. 26, 2005.
(60) Provisional application No. 60/738,872, filed on Nov. 22, 2005.
(60) Provisional application No. 60/771,546, filed on Feb. 7, 2006.
(60) Provisional application No. 60/840,407, filed on Aug. 25, 2006.

(51) Int. Cl. G02B 21/34; G03F 7/20

(52) U.S. Cl. 359/397; 430/321

(57) ABSTRACT

The present invention is a microscope microscope slide coverslip constructed of a glass or plastic plate having one or more indicia thereon which can be used to uniquely or non-uniquely identify the microscope slide coverslip or the microscope slide to which the microscope slide coverslip is attached and/or provide information therefor. Preferably the indicium, such as a barcode, is machine readable. The microscope microscope slide coverslip may have an adherent surface and a non-adherent surface, the adherent surface having a solvent activated dry adhesive film (adhesive coating) bonded thereto and having an indicium thereon for indicating the adherent side of the microscope slide coverslip. The dry adhesive film of the adherent surface is non-tacky (non-sticky) in its storage or preapplication condition. At use, the adhesive of the adherent side can be activated by a solvent.

### CROSS-REFERENCE TO RELATED APPLICATIONS

The present application is a continuation-in-part of U.S. Ser. No. 11/585,448, filed Oct. 24, 2006, which claims the benefit of priority under 35 U.S.C. 119(e) of U.S. Provisional Application Ser. No. 60/730,285, filed Oct. 26, 2005, and U.S. Provisional Application Ser. No. 60/738,872, filed Nov. 22, 2005, and U.S. Provisional Application Ser. No. 60/771,546, filed Feb. 7, 2006, the entirety of each of which is hereby expressly incorporated herein by reference.

The present application is also a continuation-in-part of U.S. Ser. No. 11/895,501, filed Aug. 25, 2007, which claims the benefit of priority under 35 U.S.C. 119(e) of U.S. Provisional Application Ser. No. 60/840,407, filed Aug. 25, 2006, the entirety of each of which is hereby expressly incorporated herein by reference.

### STATEMENT REGARDING FEDERALLY SPONSORED RESEARCH OR DEVELOPMENT

Not applicable.

### BACKGROUND

Microscope slide coverslips are typically used in the prior art to permanently cover a biological specimen affixed to a microscope slide. The microscope slide coverslip can be glass or plastic but is always transparent to enable the visualization of the biological specimen. The microscope slide coverslip is immobilized or mounted to the microscope slide with a mounting media. The mounting media is applied on top of the biological specimen and the microscope slide coverslip is placed onto the mounting media and any bubbles formed are pushed to the edges of the microscope slide coverslip to form a sealed microscope slide coverslip. Types of mounting media are well known in the art. These mounting media are collectively known as “mountants”. An early version mountant was made from the Canadian fir tree (Abies balsamea) and was known as Canadian balsam. This crude media turned yellow over time thus prohibiting the visualization of the biological specimen. More recent advances produced synthetic mountants which produced high quality, transparent, and non-yellowing microscope slide coverslip mounting medias. A type of these high quality mountants is Cytoseal™ XYL which is commercially available from Richard-Allen Scientific®.

Also known in the art are microscope slide coverslips that feature a solvent activated adhesive on one side thereof. U.S. Pat. No. 6,759,011 discloses a solvent activated adhesive microscope slide coverslip that features a protuberance on the surface thereof opposite to the adhesive side to facilitate separation of one microscope slide coverslip from an adjacent microscope slide coverslip. This protuberance, having height of at least 0.0005 inch, is necessary to keep adjacent microscope slide coverslips from sticking together during packaging. The protuberance creates an air gap between adjacent microscope slide coverslips so the adhesive doesn't stick to another microscope slide coverslip.

A significant problem associated with the microscope slide coverslip disclosed in U.S. Pat. No. 6,759,011 and a disadvantage thereof is that the protuberance on the microscope slide coverslip is costly to manufacture. The protuberance is raised above the surface of the microscope slide coverslip in the range of 0.005-0005 inches, which requires special printing or application of the protuberance material to a specific area on each microscope slide coverslip. Further, packaging of this type of microscope slide coverslip with a protuberance would be wasteful in terms of excess space requirements in the package. Since the protuberance is present on every microscope slide coverslip the spatial gaps between each microscope slide coverslip would add up quickly. The packaging could require at least 3 times the volume versus the packaging necessary for standard commercially available microscope slide coverslips.

In another disadvantage of the microscope slide microscope slide coverslip of U.S. Pat. No. 6,759,011, this protuberance could also damage a microscope objective when the objective of the microscope is being moved from one power to the next for viewing of the biological specimen. The raised protuberance on the microscope slide coverslip could hit an oil immersion objective (100×) thus causing damage to a very expensive optical grade lens. Damage could result with known automated microscopes that automatically change from low power objectives (10×) to high power objectives (100×) during an unattended scanning of a biological specimen on a mounted (microscope slide coverslipped) microscope slide. The scanning and moving of the different objectives could hit the protuberance thus causing damage to the optical objectives of the automated microscope. However, in this particular microscope slide coverslip the protuberance of this microscope slide coverslip is necessary to keep the microscope slide coverslips from sticking to each other during storage.

Another commercially available proprietary adhesive microscope slide microscope slide coverslip is manufactured by Richard-Allen Scientific®. The product name is E-Z Slips™. These adhesive microscope slide microscope slide coverslips require the use of a special and proprietary adhesive activator solution known as E-Z Slip Activator™ and E-Z Slip Activator-A™.

However, there remains a need for a solvent activated dry film adhesive microscope slide coverslip that can use common laboratory solvents like xylene, toluene, acetone, and water, without the need for special proprietary activating solutions. There is a further need of a solvent activated dry film adhesive microscope slide coverslip that doesn't require a raised “protuberance” present on a surface of the microscope slide microscope slide coverslip to separate each individual microscope slide coverslip to eliminate the microscope slide coverslips from sticking together. It is the object of the present invention to eliminate these cumbersome manufacturing problems and reduce the need for special activation solvents to gain the benefit from dry film adhesive microscope slide coverslips and to provide a microscope slide coverslip and microscope slide and microscope slide coverslip assembly which possesses other advantages not presently known or available.

### SUMMARY OF THE DISCLOSURE

The present invention is directed to a microscope slide coverslip comprising a glass or plastic plate having one or more indicia thereon which can be used to uniquely or non-uniquely identify the microscope slide coverslip or the microscope slide to which the microscope slide coverslip is attached and/or provide information therefor. In a preferred embodiment the microscope slide coverslip indicium or indicia is a barcode which is machine readable. The present invention in another preferred embodiment comprises a microscope slide coverslip comprising a glass or plastic plate having an adherent surface and a non-adherent surface, the adherent surface having a solvent activated dry adhesive film (adhesive coating) bonded thereto and the microscope slide coverslip having an indicium thereon for indicating the adherent side of the microscope slide coverslip. The dry adhesive film of the adherent surface is non-tacky (non-sticky) in its storage or preapplication condition. At use, the adhesive of the adherent side can be activated by a solvent. Prior to use or sale, the microscope slide coverslips may be stacked or adjacently placed next to another within a container such as a box or a bin. Since the dry adhesive film is dry and non-tacky, the microscope slide coverslips can remain in intimate contact with each other and not stick together and thus are easily separable during use. The dry adhesive film remains non-tacky, non-sticky under heat and cold storage (<0° C. to >100° C.). In another embodiment both the microscope slide and microscope slide coverslip disposed thereon each have at least one unique or non-unique indicium thereon for providing information regarding the biological specimen on the microscope slide or information associated with the microscope slide and microscope slide coverslip.

### BRIEF DESCRIPTION OF THE DRAWINGS

FIG. 1 is a top plan view of a microscope slide coverslip constructed in accordance with the present invention.

FIG. 2 is a top plan view of an alternate embodiment of a microscope slide coverslip constructed in accordance with the present invention.

FIG. 3 is a top plan view of an alternate embodiment of a microscope slide coverslip constructed in accordance with the present invention.

FIG. 4 is a top plan view of an alternate embodiment of a microscope slide coverslip constructed in accordance with the present invention.

FIG. 5 is a top plan view of an alternate embodiment of a microscope slide coverslip constructed in accordance with the present invention.

FIG. 6 is a top plan view of an alternate embodiment of a microscope slide coverslip constructed in accordance with the present invention.

FIG. 7 is a top plan view of an alternate embodiment of a microscope slide coverslip constructed in accordance with the present invention.

FIG. 8 is a top plan view of an alternate embodiment of a microscope slide coverslip constructed in accordance with the present invention.

FIG. 9 is a top plan view of an alternate embodiment of a microscope slide coverslip constructed in accordance with the present invention.

FIG. 10 is a side cross sectional view of the microscope slide coverslip of FIG. 9 taken through line 9-9.

FIG. 11 is a top plan view of an alternate embodiment of a microscope slide coverslip constructed in accordance with the present invention.

FIG. 12 is a side cross sectional view of the microscope slide coverslip of FIG. 11 taken through line 11-11.

FIG. 13 is a top plan view of an alternate embodiment of a microscope slide coverslip of the present invention shown as disposed on a microscope slide.

FIG. 14 is a top plan view of the microscope slide coverslip and microscope of FIG. 13 having various indicia marked thereon for example by use of a device able to apply the indicia to the microscope slide coverslip via electromagnetic radiation.

### DETAILED DESCRIPTION OF THE INVENTION

The present invention comprises a microscope slide coverslip (and method of use thereof) comprising a glass or plastic plate having one or more indicia thereon which can be used to uniquely or non-uniquely identify the microscope slide coverslip or the microscope slide to which the microscope slide is attached. Preferably each of the one or more indicia, such as a barcode, is machine readable.

The present invention in another preferred embodiment comprises a microscope slide coverslip (and method of use thereof) comprising a glass or plastic plate having an adherent surface and a non-adherent surface, the adherent surface having a solvent activated dry adhesive film (adhesive coating) bonded thereto and having an indicium (or a plurality of indicia) thereon for indicating the adherent side of the microscope slide coverslip. The dry adhesive film of the adherent surface is non-tacky (non-sticky) in its storage or preapplication condition. Prior to use or sale, the microscope slide coverslips may be stacked or adjacently placed next to another within a container such as a box or bin. Since the dry adhesive film is dry and non-tacky, the microscope slide coverslips can remain in intimate contact with each other and not stick together and thus are easily separable during use. The dry adhesive film remains non-tacky, non-sticky under heat and cold storage (<0° C. to >100° C.). The dry adhesive film may be applied to the entire adherent surface of the microscope slide coverslip or to only a portion of the adherent surface.

In a preferred embodiment, the storage of the microscope slide coverslips is in the temperature range of 0° C. to 70° C. and more preferably 20-30° C. In a preferred embodiment, the dry adhesive film of the adherent surface is an alkyd based (oil based) or aqueous based (water-based) acrylic polymer adhesive, including but not limited to methyl methacrylate, ethyl methacrylate, methyl methacrylate/ethyl methacrylate copolymer, butyl methacrylate, isobutyl methacrylate, acrylic ester copolymers, cyanoacrylates, ethyl acrylate, butyl acrylate, vinyl acrylates, alkyd bases acrylates, water bases acrylates, polyethylene, and epoxy resin polymers, and polyvinylacetate. A type of aqueous based adhesive is AquaPerm™, commercially available from Thermo Electron Corp. The adhesive can be applied by any way known in the art of applying adhesives. Curing of the adhesive can be by air drying, including forced air and heated air, conducted heat, and ultra-violet curing.

The dry adhesive film becomes sticky when activated by a solvent (including, but not limited to xylene, toluene, acetone, other organic and inorganic solvents, or aqueous solvents including water, ethanol, methanol or other alcohols). Once in contact with the activating solvent, the dry adhesive film becomes soft and sticky and is then ready to be placed over a specimen on a microscope slide or another plate. After the activated (tacky) adhesive of the adherent surface is placed in contact with the specimen and the microscope slide, the adhesive layer on the microscope slide coverslip becomes hard and permanently seals the microscope slide coverslip to the microscope slide thereby enclosing the specimen between the microscope slide coverslip and microscope slide or other plate. In a preferred embodiment the time required for the adhesive to change from a tacky condition to a dry (hardened) state is less than one minute.

In an alternate embodiment the dry adhesive film is of an aqueous based resin that is activated by a aqueous solvent (e.g., water) so as to protect leaching of chemical dyes impregnated into the specimen by dye-incompatible solvents (e.g., certain organic solvents). The dry adhesive film on the adherent side of the microscope slide coverslip is preferably in the thickness range of less than 0.001 μm to greater than 100 μm. Preferably the thickness of the dry adhesive film is the range of 20-60 μm.

The dry adhesive film of the present invention when dried typically has a hard and brittle consistency or character. To activate the hard dry adhesive film of the adherent surface to a soft sticky condition, the solvent is put in contact with the dry adhesive film and preferably includes a step of applying pressure to the non-adherent (opposite, non-coated) side of the microscope slide coverslip so as to cause penetration of the solvent into the dry adhesive film to soften it to a sticky adherent phase. The pressure applied to the microscope slide coverslip is preferably between 0.01 to 10 psig. Preferably the pressure applied is in the range of 0.01 to 2 psig. This pressure not only facilitates penetration of the solvent into the dry adhesive film to activate it into a sticky adherent condition, but also pushes out any residual solvent away from the adhesive to leave a stoichimetric amount of solvent and adhesive to produce a consistent softening of the dry adhesive which is reproducible and consistent with each application. In an alternate embodiment, the dry adhesive film has a pattern when applied to the microscope slide coverslip to indicate the adherent side of the microscope slide coverslip.

Problems can occur if the user of the dry adhesive film microscope slide coverslip inadvertently is unable to readily identify which side of the microscope slide coverslip has the dry adhesive film thereon. For example, if the microscope slide coverslip is dropped on a counter or a floor, the orientation of the microscope slide coverslip may be altered, causing distress, loss of time, and expense for the technician. In such a case, the technician must determine which side of the microscope slide coverslip has the dry adhesive film. Since the dry adhesive film may be substantially optically clear, the technician may have difficulty determining which side of the microscope slide coverslip is which. If the proper orientation of the coating is not identified quickly, the technician might inadvertently attempt to seal the wrong side of the microscope slide coverslip (i.e., the uncoated, non-adherent side) to the slide. In such a case, the microscope slide coverslip would not adhere to the slide and the dry adhesive film of the microscope slide coverslip would be damaged and the microscope slide coverslip would have to be discarded and, further, the specimen on the slide may be damaged or lost.

To solve or avoid such problems, the present invention contemplates marking the microscope slide coverslip with one or more indicia in such a way as to make the orientation of the microscope slide coverslip (i.e., the location of the dry adhesive film on the microscope slide coverslip) unambiguously evident and apparent.

For example, in one embodiment of the present invention, the microscope slide coverslip has a visually identifiable or machine identifiable indicium thereon (on either the adherent or non-adherent side).

In one embodiment, these indicia can be marked by a laser (such as the laser used to cut the coated sheets of glass or plastic into the size of usable microscope slide coverslips). Initially, for example, the laser can etch the glass or plastic in a specific location on each microscope slide coverslip in an exact position before or after the final cutting of the microscope slide coverslip.

For example, the indicium (e.g., a dot, mark, code, barcode, label, or other feature indicated herein) could be etched in a corner of the non-adherent side of the microscope slide coverslip (such as the lower left corner) such that the dry adhesive film is on the side of the microscope slide coverslip opposite the side of the microscope slide coverslip having the indicium. If the technician loses track of the adherent side of the microscope slide coverslip, all the technician must then do is pick up the microscope slide coverslip, identify the indicium thereon, and properly orient the microscope slide coverslip with the adherent side facing downwardly, then place the microscope slide coverslip onto the microscope slide in the normal manner. These indicia can be dots, markings, patterns, arrows, symbols, letters, numbers, lines, regular or irregular shapes for example circles, boxes, or triangles or any insignias or other appropriate or feasible markings readable and/or identifiable by a machine or the human eye. Examples of such indicia are shown for example in FIG. 14 and are designated therein by reference numeral 158. The microscope slide coverslip may have a rounded, notched, or nicked, abraded, or colored edge or corner or a concave depression or a hole in the microscope slide coverslip to indicate the adherent side of the microscope slide coverslip. In another embodiment, a rough or abraded surface of the dry adhesive film of the microscope slide coverslip may itself comprise the indicium.

For use with an automated microscope slide coverslipping instrument, the microscope slide coverslips are preferably marked with at least one machine-readable indicium for identification of the microscope slide coverslip and/or for distinguishing the adherent side of the microscope slide coverslip. If the orientation of the microscope slide coverslip was determined by the instrument to be incorrect, the technician would be notified to rearrange the microscope slide coverslip into the proper orientation to continue the automated microscope slide coverslipping process.

As noted above, each microscope slide coverslip preferably has at least one indicium and one adherent side having a solvent activated dry adhesive film thereon, may be present on either surface (or the edge) of the microscope slide coverslip. These indicia can be the same for each microscope slide coverslip in a batch or may be unique such that each microscope slide coverslip can be distinguished from every other microscope slide coverslip in the batch or may be universally unique. These unique indicia can be useful in the secondary or alternative identification in association with a separate indicium present elsewhere on the microscope slide (such as a unique barcode) that is present before testing and thus which would be associated with the identity of each unique slide for a particular patient or biological sample thereon.

In one embodiment of the invention a microscope slide and a microscope slide coverslip in combination comprise a microscope slide testing and identification system (a microscope slide-coverslip assembly), wherein the microscope slide has at least one primary indicium and the microscope slide coverslip has at least one secondary indicium. In this embodiment, the secondary indicium of the microscope slide coverslip (i.e., a machine readable indicium, alternative identification indicium, and/or informational indicium) can be a unique or non-unique indicium, which provides additional machine readable or visual identification, meaning, or information when the biological specimen has been permanently (or even temporarily) preserved by the mounting of the microscope slide coverslip bearing the secondary indicium, for example after the testing or evaluation process is complete. The now completed and preserved microscope slide could be scanned for the secondary machine-readable indicium (or analyzed or any other form of indicium) present on the microscope slide coverslip to further identify the patient's sample or test data by assigning the test data or other information to the secondary indicium (“secondary information”) and linking or associating it to the primary (original) indicium (“primary information”) present before testing began.

This method of scanning or analyzing the secondary indicium of the microscope slide coverslip, of the present invention, for identifying the “end of testing”, and or “sign out” (or other aspect of processing) can be of importance in modern day tracking of the microscope slide from the time the microscope slide is prepared with the biological specimen thereon throughout the process of “reporting” the test. The term “sign out” or “signed out” refers to when the biological specimen has given a result or diagnosis by a technician or physician and is finalized. The term “reported” refers to the process of reporting the results (e.g., by fax, email, electronic file, electronic signature, etc.) to the ordering physician or institution or database. Prior art tracking systems utilize only the primary indicium (original unique machine readable code) assigned to the microscope slide and specimen (i.e., a single identification code is used) when testing is started. In prior art systems, there is no secondary indicium (alternative or secondary machine readable marking) present on the microscope slide-coverslip assembly for secondary or back up identification thereof, or no unique or non-unique machine readable secondary indicium present on the microscope slide that can be scanned and supply secondary or additional information such as that “the test is now completed” and or “the test has been reported” or “signed out” for example.

In the present invention, the physician or technician or other user can scan or read the secondary indicium of the microscope slide coverslip when the test is complete, or any other time, e.g., alternatively, the secondary indicium can be scanned or read by a physician or technologist, for example, after the microscope slide is read to identify the result of the test (e.g., signed out). This method of recording a “finish test” scan, “signed out” scan, or “reported” status with a second indicium (i.e., an indicium, different or alternative machine readable code or symbol) on the microscope slide coverslip (i.e., other than the original code or symbol (primary indicium) assigned to the microscope slide prior to testing), will be useful in tracking the specimen on the slide throughout the “sign out process” or “reporting process”. The microscope slide coverslips of the present invention can have one or more unique, non-unique (or combinations thereof) machine readable secondary indicia present on the upper and or lower surfaces for scanning, reading, or machine logging of data related to “finished testing”, “physician name”, “technologist name”, “sign out time and date”, or any other data related to “sign out” or “reporting” of the microscope slide test. In another embodiment of the invention, the microscope slide-coverslip assembly may have an indicium only on the microscope slide coverslip thereof.

The microscope slide coverslips of the present invention thus may have more than one secondary indicium present thereon so that different personnel who may come in contact with, utilize, or process the microscope slide having the biological specimen thereon can choose a separate secondary indicium (e.g., encoding separate “secondary information”) to scan related to the data they are trying to log into their laboratory information system (LIS). In one non-limiting example, two secondary indicia are present on the microscope slide coverslip, wherein an initial secondary indicium can be used by the processing technician to indicate the “end of test”, and a second secondary indicium can be used for the physician's “sign out”. The “end of test” (initial) secondary indicium can be a unique or non-unique machine readable indicium to be scanned (processed) by the technician when the test is complete. The “physician sign out” indicium (the “second” secondary indicium), can be scanned (processed) by the physician or medical professional after the specimen has been reviewed and a decision has been made (by the physician or medical professional) regarding the outcome of the test.

The meanings and information associated with the primary and/or secondary indicia may be recorded manually and/or mechanically using various devices known in the art.

There may be one or several types of secondary indicia present on each microscope slide coverslip of the present invention. An additional secondary indicium can be marked on the microscope slide coverslip after it has been secured to the slide, for example by activation of a laser or light activatable material on or in the microscope slide coverslip as described in further detail below. The secondary indicium can be unique to each microscope slide coverslip. The secondary indicium can be non-unique relating to codes that have the same information. Examples of non-unique secondary indicia are indicia that once scanned, indicate or represent the same information (e.g. repeatable information, canned dictations, repeatable phrases) such as “the test has been completed”, containing the “sign out data” of the physician or medical professional, and/or the “type of test” performed (e.g., FISH). These types of indicia eliminate the entry of data manually by personnel in regard to, for example, the time and date of the “end of testing”, and/or the time, date and name of the physician upon “sign out”, and/or the “type of test performed”.

In accordance with the present invention, each physician or technologist could have his or her own particular secondary indicium on the microscope slide coverslip of the present invention to scan and link his or her information and thus assigning and linking this information with the primary indicium present on the microscope slide. For example, the laboratory's own LIS could be programmed to accept the unique or non-unique secondary indicia by means of scanning the unique secondary indicia thus linking the secondary indicia electronically with the patient's primary identification information related to the primary indicium.

The Shanndon Checkmate® manufactured and distributed by Thermo Fisher Scientific, Waltham, Mass. 02454, is one example of a hand held instrument which has been used in labs to track microscope slides and processing cassettes having machine readable codes (primary indicia) thereon. A microscope slide, with a primary indicium thereon as known in the prior art, can be scanned by this hand held device. The information (e.g., patient information) regarding the microscope slide is stored in the hand held unit, for example. The technician would then scan the paraffin processing cassette (a device known in the art) which holds the biological specimen for that particular microscope slide and would then link the primary indicium from the microscope slide with the machine readable code from the paraffin processing cassette. The microscope slide and the biological specimen processing cassette associated therewith can be rescanned when the biological specimen is being placed on the microscope slide to confirm that a particular specimen is associated with that particular microscope slide to reduce errors. This is a limitation of this prior art technology.

In the present invention, the secondary indicium (indicia) is (are) present on the microscope slide coverslip at the time of preservation of the biological specimen and completion of the testing protocol. The technician or physician can then rescan the primary indicium of the original microscope slide, thereby retrieving or recalling the patient information, and can link it with the secondary code, and or with information from the one or more secondary indicia present on the microscope slide coverslip (in accordance with the present invention) to provide a “secondary identification” or “additional information” regarding the “type of test”, “end of test”, “sign out”, “technician's” or “physician's” information, “parameters of the test”, or other “specifics” of the test. The secondary indicia on these novel microscope slide coverslips of the present invention may be unique machine readable codes or non-unique machine readable codes, or visual data, visual codes or symbols as indicated elsewhere herein. The secondary indicia can correspond to visual data on the microscope slide coverslip such as words, codes, symbols, numbers, and letters to let the technician or physician know what particular type of test was performed (e.g. IHC, ISH, CISH, FISH, PCR, or other types of stains, for example). A conventional scanning device can be modified to use the novel method of scanning single or multiple secondary indicia on microscope slide coverslips as contemplated in the present invention. In a preferred embodiment of the present invention single or multiple secondary indicia present on a microscope slide coverslip can be scanned with a hand held or mobile scanning unit programmed to link, decipher, or store, the information encoded by the secondary indicia. The conventional scanning unit could also be wired to a LIS via USB connection, or firewire connection, for example. The preferred embodiment of transfer of the data from a hand held scanner to a LIS (e.g., a main frame or other central processing unit) could be by the use of wireless or Bluetooth™ technology for example. The technician(s) and/or physician(s) or other medical professional(s) could have a scanning unit to scan one or more appropriate primary or secondary indicia and the information encoded therein would be transferred in real time to the main frame or CPU of the LIS to update the progress of the testing of the biological specimen on the microscope slide without the need of manually entering the testing data by personnel once the test is completed and signed out. The LIS database could therefore be updated in real time as to the status of the biological specimen present on the microscope slide to increase productivity and reporting thereof. The physician or technician or other appropriate individual could thus track the progression of the testing protocol for the microscope slide in real time and reporting personnel could track the “sign out” process in real time.

The microscope slide coverslip of the present invention can optionally have a transparent or invisible developable (light activatable) coating present on the upper side or lower side thereof as described for example in U.S. application Ser. Nos. 11/895,544 and 11/895,501. This developable coating can be developed, as described in the above-referenced applications, before or after the microscope slide coverslip is attached to the microscope slide. This coating can be developed by a device which emits laser or other source of visible, non-visible, infrared, ultraviolet, or specific wavelengths of emitted radiation or any combinations above. The intensity of the electromagnetic wavelength(s) can be high, medium, or low intensity or any other intensity or strength known in the art of emitted light radiation, known herein as developable wavelengths. These developable wavelength(s) can mark or label the upper or lower surface of the microscope slide coverslip that have a transparent or invisible developable layer thereon, to further label or identify the microscope slide coverslip, and/or microscope slide with the biological specimen attached thereto. The developable coating present on the microscope slide coverslip, once developed, can produce any markings know in the art for identifying the microscope slide coverslip, microscope slide, and/or biological specimen attached to the microscope slide. The developable markings may be, but are not limited to, machine readable codes, visible readable codes, symbols, letters, words, phrases, canned dictations, dots, lines, numbers, characters, or any combination of the above.

In a preferred embodiment the device for applying the developable wavelengths can be a hand held device, for example shaped like a pen, or pointing device (e.g., see FIG. 14) that is battery or AC operable. Once the microscope slide coverslip is attached to the microscope slide for preserving the biological specimen thereon, with the processing of the biological specimen now completed, the technician or physician can write, draw, number, or otherwise mark or develop the coating on the microscope slide coverslip to further identify or mark the microscope slide coverslip relating to the biological specimen information. The technician could mark the microscope slide coverslip with the words “completed” including a “date”, “time”, or type of “test” for example. An example of such a marking is the type of test performed on the slide such as “IHC” for immunohistochemical stain or “HMB-45” for anti-melanoma antibody. The physician and technician could mark special areas of interest around the biological specimen like “circling” areas, numbering areas “1” or pointing to areas with an arrow or any other type of markings as in conventionally made with an ordinary felt tip marker known in the art of marking microscope slide coverslips.

Alternately, a beam of electromagnetic radiation (e.g., laser) can be applied directly through a lens or objective of the microscope while the microscope slide is disposed upon the stage thereof. The electromagnetic radiation can be directed to a specific and discrete portion of the microscope slide while the biological specimen (before or after a microscope slide coverslip has been applied to the microscope slide to cover the biological specimen) is being viewed under the objective or lens of the microscope by the pathologist or technician and thereby “mark” a portion of the microscope slide coverslip or microscope slide to mark a portion thereof near or in the biological specimen. The electromagnetic radiation can be directed or localized by using the lighted arrow or pointer apparatus that is known and used in the art to visually “see”, “indicate” or “point to” a specimen using a lighted arrow that is seen transposed above the image of the biological specimen. These conventionally known and used illuminated pointers are usually manipulated by an associated joystick either on the microscope or as an attachment to the microscope. As contemplated herein, an electromagnetic radiation emitting device can be incorporated into the pointer apparatus for causing emission of the electromagnetic radiation onto and through the microscope slide coverslip, therefore developing a specific area of the microscope slide coverslip or microscope slide in relation to the biological specimen. The pathologist or technician can move the illuminated pointer to point to or rest on a specific place on the slide and then activate the electromagnetic radiation by “pointing”, “drawing”, or otherwise moving the point of the electromagnetic radiation about the slide to develop and thereby mark a portion of the microscope slide coverslip or slide. This electromagnetic radiation from the pointer apparatus could be used to draw a line, an arrow, a circle, a dot, a box, or any other visual indicium to mark the microscope slide coverslip or slide in relation to the biological specimen. This development of the mark by the electromagnetic radiation from the illuminated pointer (or other apparatus associated with the illuminated pointer or a “stand-alone” electromagnetic radiation emitting apparatus attached to the microscope) can be accomplished even while the pathologist or technologist is viewing the biological specimen through the eyepiece of the microscope. The electromagnetic radiation wouldn't harm the eyes of the user because the radiation would not be directed toward the microscope eyepiece but rather only toward the microscope slide or microscope slide coverslip over the biological specimen. The user could in “real time” mark areas of the microscope slide coverslip or microscope slide by moving the electromagnetic radiation pointer about the microscope slide coverslip or microscope slide while visually viewing the biological specimen through the microscope eyepiece, thereby marking the microscope slide coverslip or microscope slide to uniquely and permanently identify areas of the biological specimen for archival viewing at a later date.

The developable wavelength device can utilize a wavelength that is of the semi-conductor type. Examples of this type are known in the art of hand laser scanning devices. Other lasers are know in the art that can be use with the present invention developable coated microscope slide coverslip are CD-ROM and CD-RAM writers that use light to activate a coating on the CD's label side. The CD with its special coating on the label side is developed by a semi-conductor type low intensity laser. One type of laser and special coating CD's known in the art of labeling CD's is manufactured by Hewlett Packard and sold under the trade name LightScribe®. The hand usable device (i.e. a pen or pen-like device), can have a small semi-conductor type laser present in the tip of the device. The distal end where the laser is emitted from can have incorporated within the tip a device such that when the tip of the device touches the microscope slide coverslip, the physical pressure applied to its external tip would activate the laser and emit the required wavelength to develop the coating on the microscope slide coverslip. The laser wavelength would therefore only be turned on when the tip of the device is pressed to the microscope slide coverslip and not before. Therefore the device is only activated when pressure is sensed at the tip of the device. If the device was constantly emitting the developable wavelength, the user could not write or draw effectively. When the tip of the device touches the microscope slide coverslip, the light is activated or can be delayed to come on once it is pressed to the microscope slide coverslip within a few milliseconds. The device is turned off immediately once the pen is not touching the microscope slide coverslip. This pressure sensing device for turning on and off the device is efficient just like a regular ink pen which causes ink to flow onto a substrate when the tip of the device touches the substrate.

In an alternate embodiment, the developable coating can be marked with a hand held device that can store predetermined information such as canned dictations like “test is complete”, “type of test”, Physician or Technician “Name”, the “Date” or the “Time Completed”. This device can have, for example a semi-conductor laser or other type of electromagnetic radiation-illuminating means such as an intense light and the user of the device could type or write or even speak the information into the device and the device could then emit a laser (or other illuminating radiation) with that digitized information or other “slide-specific information” onto the developable coating present on the microscope slide coverslip. The device can have a key pad (or its equivalent) present with letter, number, or symbols such as on a “PDA” (Personal Digital Assistant), that can be typed into or otherwise recorded within the hand held device and stored for later emission (e.g., recordation by illumination) to the developable coating present on the microscope slide coverslip which may or may not have prior indicia present thereon. This hand held device can be placed over the microscope slide coverslip (or, the slide could be inserting into a slot within the device) and activated to develop the coating within milliseconds for example to provide the slide-specific information shown on the lower end of the microscope slide of FIG. 14 as discussed in more detail below.

In an alternate embodiment, the developable coating is on the lower side of the microscope slide coverslip, with or without an indicia present or with or without dry film adhesive present on one side. The advantage of having the developable coating on the bottom (lower surface) of the microscope slide coverslip is that when the microscope slide coverslip is mounted to the microscope slide, the adhesive used to bond the microscope slide coverslip to the microcopy slide protects the developable layer as well as secures the microscope slide coverslip to the slide. A further advantage is that the developable coating is protected from environmental elements (e.g., abrasion, chemicals, chipping) by the upper surface of the microscope slide coverslip, the microscope slide coverslip adhesive, and microscope slide below the microscope slide coverslip. The developable wavelength can now pass through the top surface of the microscope slide coverslip through the microscope slide coverslip and develop a portion of the developable coating. The developable coating is thus sandwiched between the cover glass, adhesive, and microscope slide. In a further advantage of having the developable coating on the lower surface of the microscope slide coverslip, when a technician or physician marks the developable layer, the marking is below the surface of the upper surface of the microscope slide coverslip and thus is not able to come in contact with or interfere with the microscope lens, thereby permanently eliminating the potential of damage to the lens of the microscope by touching the developable coating or marking therein. This is a direct contrast to the markings produced by prior art methods or devices (e.g., felt tip pen markings) which can come in contact with the lens of the microscope and thus stain or damage the lens due to direct touching of the microscope lens to microscope slide coverslip markings. In a further advantage of having the marking on the lower surface of the microscope slide coverslip, the planes of focus of the marking in relation to the microscope lens and the biological specimen are much closer. In the prior art method wherein a marking is made by using a marking of a permanent marker (e.g., a felt tip pen), the plane of focus of the marking is higher or raised appreciably above the plane of focus of the biological specimen thus making it difficult to have both the marking and biological specimen in focus simultaneously. When the marking is on the upper surface of the microscope slide coverslip, the biological specimen (in a lower plane of focus) is appreciably out of focus when the user focuses on the marking. Alternatively, when the user focuses on the biological specimen, the markings of the upper surface (also in a different plane of focus) are now appreciably out of focus. A user cannot have both the marking and the biological specimen in focus at the same time with the prior art methods wherein markings are on the upper surface of the microscope slide coverslip.

However, with the microscope slide coverslip of the present invention, which in this embodiment has a developable layer on the lower surface of the microscope slide coverslip, the plane of focus is appreciably the same for both the marking and the biological specimen. This is advantageous when a user is viewing a biological specimen through a microscope and must view the marking(s) on the microscope slide coverslip in relation to the biological specimen in relatively the same plane of focus (or plane of view). An example of the requirement of the biological specimen to be in the same or relative plane of view with the developable marking occurs when the user has marked an area on the microscope slide coverslip with a grid and the grid, has numbers associated with said grid. The grid with numbers present thus would be seen in the same or relative plane of focus of view in relation to the biological specimen. Both the grid and biological specimen could be viewed in the same plane of vision or focus.

A further value of the unique secondary indicium present on the microscope slide coverslip, is its use in enabling identification of the microscope slide in the event the primary identification marking or primary indicium of the microscope slide is lost or separated from the portion of the microscope slide having the biological specimen (e.g., due to breakage or peeling of the primary identification markings from the microscope slide). In this case, the secondary indicium of the microscope slide coverslip could then be used as an identifier for the microscope slide. When the microscope slide coverslip is attached to the microscope slide, the area of the microscope slide covered by the microscope slide coverslip is now thicker than the rest of the microscope slide (due to the two layers of slide and microscope slide coverslip) and the adhesive layer of the microscope slide coverslip positioned over the biological specimen which protects the specimen from breakage and total separation. The secondary indicium present on the microscope slide coverslip (if unique) would then serve to identify the biological specimen even if most of the microscope slide is missing, lost or broken away from the biological specimen.

As noted above, in another preferred embodiment of the invention, the microscope slide coverslip may have a non-unique or unique orientation indicium thereon even without dry adhesive film thereon for secondary identification of the patient's biological specimen. Thus a unique indicium can be applied to the microscope slide coverslip for orientation of the dry adhesive film (the “adherent” side) and/or for use in identification of the patient.

The indicium can be placed on the microscope slide coverslip by laser engraving, or frosting the indicium into the plastic or glass microscope slide coverslip for example. When the microscope slide coverslip has an adherent side, the indicium can be on the adherent side of the microscope slide coverslip or on the non-adherent side of the microscope slide coverslip. Preferably the indicium would be on the non-adherent (upper) side of the microscope slide coverslip, although alternatively the indicium can be on the adherent (lower) side of the microscope slide coverslip.

The microscope slide coverslips of the present invention can be of any size known in the art of microscope slide coverslips. Examples of preferred microscope slide coverslip thickness include, but are not limited to, the industry standard sizes of “1”, “1.5”, or “2” having thicknesses of 0.08 mm to about 0.35 mm, for example, and preferably 0.152 to 0.19 mm in thickness. Examples of width and length include, but are not limited to, the industry standard sizes of 18×18 mm, 22×22 mm, 24×30 mm, 24×50 mm, 25×25 mm, 11×22 mm, 48×60 mm or circular microscope slide coverslips, such as those having standard diameters of, for example, 12 mm and 18 mm, may also be used. The microscope slide coverslip of the invention can be made of plastic or glass. The width, for example, may be in a range of 10 to 50 mm and the length, for example, in a range of 15 to 60 mm when the coverslip is rectangular. When the microscope slide coverslip has a circular shape the diameter may be, for example, 10-25 mm.

In a preferred embodiment the microscope slide coverslip of the invention is constructed without a removable or non-removable polymeric backing (i.e., a protective coating or release layer) which covers the non-adherent side thereof.

In one embodiment non-unique indicia of the present invention can be one or more letters placed at an asymmetric position on the microscope slide coverslip to distinguish the adherent and non-adherent sides of the microscope slide coverslip. For example, the indicium may be in the lower left hand corner of the non-adherent side in one particular batch of microscope slide coverslips. The user will know, for example, that when the indicium is in a lower left position, the adherent side is facing downwardly. These letters could stand, for example, for different types of adhesives present on the microscope slide coverslip. For example, the letters “XL” could indicate the solvent needed to activate the adhesive is “xylene”. Another example is the letters “AQ”, which would indicate the need to use of an aqueous based solvent to activate the adhesive. Various dry adhesive film thicknesses as can be identified by letters or numbers such as “CY” for cytology specimens that need a dry adhesive film larger of, e.g., 50 μm on the microscope slide coverslip. These letters can be placed anywhere on the microscope slide coverslip in an asymmetric location to enable the technician to efficiently and properly orient the microscope slide coverslip for use.

Indicia used herein are defined as any marking produced by a laser or other glass or plastic etching or printing means or manufacturing means into or onto a surface of the microscope slide coverslip which are identifiable by the human eye or machine-readable instruments, and may include, but are not limited to, insignias, numbers, codes, barcodes (including 1-dimentional and 2-dimentional barcodes), symbols, other machine and eye readable patterns, letters, lines, or shapes or other marking as identified elsewhere herein.

Examples of barcodes contemplated for use in the present invention include, but are not limited to, symbologies having square, rectangular, circular, or irregular shapes and more specifically may include symbologies known as EAN-13, EAN-8 EAN-128, UPC-A, UPC-E, Code 11, Code 39, Code 93, Code 25, Code 128, Codabar, MSI, Jan 13, Jan 8, Plessey, Telepan, Interleaved 2 of 5, Discrete 2 of 5, 2-dimensional and RSS barcodes including Data Matrix, PDF417, Maxicode, Aztec Code, QR code, Micro PDF417, Samsung PDF417, Data Code, Code 49, 16K, RSS14, RSS limited, RSS Expanded, 2D Pharma Code, Glaxo Smith Kline, HIBC, IKS, IMH, Kurandt, Novartis Pharma, Pharma Code, PZN, and OCR formats. The indicia can be visual symbols like codes, letters, and words for the technician and physicians to visually read for information regarding the test performed or other additional information. This size of the barcode indicia on the microscope slide coverslip may be in the range, for example, of 1 to 3 mm wide and 1 to 50 mm long (preferably 1-2 mm wide and 2-15 mm long) when having a rectangular shape and 3 to 6 mm (preferably 4-5 mm) in dimension when square.

Herein, where the indicium is defined as informational, the indicium preferably comprises one or more letters, numbers, symbols, characters, and/or patterns which represent information, data, or a message and wherein the informational indicium may or may not serve to identify the adherent side of the microscope slide coverslip. For example, the microscope slide coverslip could include an indicium for identifying the adherent side of the microscope slide coverslip, and an indicium for representing information. Alternatively the microscope slide coverslip could include an indicium for only indicating the adherent side or only an informational indicium.

In one embodiment the laser or other etching means produces the indicium by removing a portion of the microscope slide coverslip surface, therefore, the level of the indicium is lower than the original microscope slide coverslip surface. Indicia produced by a laser may appear engraved below the surface or have a frosted appearance. The lasered indicium may be colored to increase the visibility of the indicium by any manner known in the art of coloring or filling engraved surfaces. This filling or coloring can be of any color known in the art of utilizing coloring inks or coloring enhancing treatments.

As noted above, an indicium can be positioned on the microscope slide coverslip to locate the adherent side of the microscope slide coverslip for mounting over biological specimens. These indicia can be located on either side or any edge of the microscope slide coverslip and are at least partially localized at these positions.

In a preferred embodiment, the indicium can be of a visible substance that is soluble in the solvent that activates the dry adhesive film. In this embodiment the solubilizable indicium, preferably a removable or disappearing ink, is present on the microscope slide coverslip in an asymmetric fashion (on either side or edge of the microscope slide coverslip, i.e., any surface). Before use, the indicium is dry, adhered, and visible on at least one area in an asymmetrical location on at least a portion of the microscope slide coverslip. The indicia may have color, or are otherwise visible to indicate their position on the microscope slide coverslip. The indicium can be seen by the technician and the adherent side is quickly identifiable by the technician since the indicium is present in an asymmetric location on the microscope slide coverslip. Once the microscope slide coverslip is mounted upon the microscope slide, the indicium in this embodiment is rendered invisible or colorless due to solubility of the indicium or chemical reactivity of the indicium causing the indicium to become invisible with the activating solvent that activates the dry adhesive film. The indicium becomes invisible with the solvent alone or can be wiped away from the microscope slide coverslip by wiping the solubilized indicium with the residual solvent present around the microscope slide coverslip or solvent which is added. The solubilized visible indicium can be wiped away leaving it less visible, completely invisible, at least partially removed, or completely removed from the microscope slide coverslip. It should be understood the indicia are visible marks placed on the microscope slide coverslips in an asymmetrical position as to distinguish the location of the adherent side (bottom side toward the microscope glass) of the microscope slide coverslip, in relation to the non-adherent side (upper side, facing away from the microscope slide) thus enabling the microscope slide coverslip to be oriented in the correct position for mounting on the slide.

In alternative embodiments, the indicia may be opaque, transparent with or without color, or translucent with or without color. The indicium may have a thickness (i.e. an elevation above a surface) of less than or equal to 10⁻¹⁰ inch, 10⁻⁹ inch, 10⁻⁸ inch, 10⁻⁷ inch, 10⁻⁶ inch, 10⁻⁵ inch, or 10⁻⁴ inch, or may have a depth (below a surface) of 10⁻¹⁰ inch, 10⁻⁹ inch, 10⁻⁸ inch, 10⁻⁷ inch, 10⁻⁶ inch, 10⁻⁵ inch, or 10⁻⁴ inch. Preferably the thickness of the indicium when elevated is less than or equal to 0.001 (10⁻³) inch (2.54×10⁻² mm). The indicium may be an altered corner or edge of the microscope slide coverslip which is different from the other three corners or edges of the microscope slide coverslip which are identical to each other. For example the altered corner indicium may be a rounded corner or an angled (truncated) corner. The indicium may be a barcode, symbol, code, number or insignia, or any other indicium described herein, and may be etched (e.g., by a laser) or printed onto the microscope slide coverslip or produced by other means known in the art. The indicium may be machine readable, and may be unique for each microscope slide coverslip or batch of microscope slide coverslips. The indicia of the microscope slide coverslips in a particular batch may be in a successive series for enabling the unique identification of the slide upon which the microscope slide coverslip is placed. The indicium may be permanent or removable (for example by the solvent used to activate the dry adhesive film). The indicium may be an asymmetrical alteration of the structure of the microscope slide coverslip, e.g., with a notch, nick, hole, incision, or laterally-extending edge protuberance, or other physical alteration.

The indicium may be for example at least one dot, circle, mark, code, barcode (including 1-dimensional and 2-dimensional barcodes as described elsewhere herein), label, character, shape, symbol, letter, number, line, insignia, physical alteration of the microscope slide coverslip, pattern, color, holographic image, or iridescent image, any of which may be machine readable, and any of which may be raised above or etched below one or both surfaces of the microscope slide coverslip. The indicium may be printed with an ink and preferably has a thickness of less than 10⁻² inch, 10⁻³ inch, 10⁻⁴ inch, or less than 10⁻⁵ inch (or less as indicated above). A unique or non-unique machine readable indicium, or a visually readable symbol, code, letter, or word indicium can have a thickness greater than 1×10⁻⁴ inches, such as a thickness of 10⁻³ inches, 10⁻² inches, 10⁻¹ inches.

The unique or non-unique machine readable indicium, or a visually readable indicium comprising a symbol, code, letter, or word can be present on the upper or lower surface of the microscope slide coverslip, with or without dry film adhesive present on one side. If the microscope slide coverslip has dry film adhesive present on the side where the unique or non-unique machine readable indicium is present, the unique or non-unique machine readable indicium would be adherent to the glass with the dry film adhesive placed over the unique or non-unique machine readable indicium. The unique or non-unique machine readable indicium could then be scanned by a machine readable source (i.e., laser) by passing the required wavelength through the topside of the microscope slide coverslip, and through the thickness of the microscope slide coverslip, thereby identifying the code secured on the lower surface of the microscope slide coverslip (the surface adjacent the upper surface of the microscope slide.

When printed on the microscope slide coverslip, the ink may be applied by screen printing, pad printing, lithography, laser jet, ink jet, offset printing, roll printing, barrel printing, or stamping, or any other technique known to those of ordinary skill in the art. Curing of the adhesive can be by air drying, including forced air and heated air, conducted heat, and ultra-violet curing. Preferably the ink comprises a pigment (opaque, transparent, or translucent) with or without a silane linking component or curing catalyst. The ink can be of any known in the art for producing a visual contrast to the glass or plastic plate and that has a thickness of less than 0.0001 inch after cure. Preferably the thickness of the ink is less than 0.00001 inch. Ink types like epoxy and acrylics are known and can be used for the present invention.

The indicium can be a delineated or structural alteration to the microscope slide coverslip, including a removed portion of a corner, such as a rounded corner, or a truncated corner. The removed portion can be a line, nick, notch, and/or cut in the microscope slide coverslip. The structural alteration is a removed or asymmetrical alteration to the structure of an otherwise standard square, rectangular, or circular symmetrical commercially available microscope slide coverslip. In those embodiments of the present microscope slide coverslip wherein the indicium is a structural deletion from the plate (e.g., a rounded corner, notched corner, hole, cut corner), the automated microscope slide coverslipping instrument may have a complementary storage hopper or container to hold and store the microscope slide coverslips. This storage hopper or container preferably would have a component, e.g., a complementarily shaped surface, for engaging the indicium (e.g., angled) or a rod for engaging an indicium hole.

In an alternate embodiment, the invention comprises a developable microscope slide coverslip which is constructed from a developable liquid microscope slide coverslip media that is spread over the microscope slide at the end of testing to preserve the biological specimen disposed thereon without the need for a separate glass or plastic microscope slide coverslip being attached to the slide via a common mounting medium. The developable microscope slide coverslip can be made by the liquid microscope slide coverslip media, of the present invention, that can be spread thinly over the biological specimen by a gap coater or similar applicator that can make a thin coating from the liquid media. The microscope slide coverslip media thus could be placed in front or rear of the gap coater and then the coater moved about the slide to lay down a specific thickness of media in accordance with the specific gap coater device. In one example, the gap coating device has a gap of 8 microns away from the substrate, or microscope slide. The microscope slide coverslip liquid media is placed in front of or behind the gap coater. The gap coater is then moved linearly from at least one end of the microscope slide to the other end of the microscope slide. The movement of the gap coater may be from the distal end from the labeled end of the microscope slide toward the labeled end, or vice versa. The microscope slide coverslip liquid media is trapped in the “gap” of the gap coater and is spread across the slide. In this particular non-limiting example, the microscope slide coverslip media is spread evenly at a thickness of 8 microns, for example. Gap coaters with gaps of other thicknesses of course are known in the art. The final dried thickness of the developable microscope slide coverslip media coating is dependent on the evaporative shrinkage of the microscope slide coverslip media during the curing process from the solvent present in the microscope slide coverslip media thereby “curing”, “drying”, “hardening”, or otherwise “setting” the microscope slide coverslip media over the microscope slide to preserve the biological specimen without the use of a separate glass or plastic microscope slide coverslip being used with conventional mounting media between the glass or plastic microscope slide coverslip and the microscope slide. In a preferred embodiment of the present invention, the liquid microscope slide coverslip media is evenly spread across a microscope slide at a predetermined and specific thickness based on the thickness of the gap of the gap coater mentioned above, in relation to the upper surface of the slide and can have the transparent developable properties mentioned in detail elsewhere in this application. The liquid microscope slide coverslip media, of the present invention may, for example, comprise photo-developable or heat developable chemicals or agents present therein which, once the media is “cured”, “hardened” or otherwise dried to a transparent film or coating on the microscope slide, can be “developed” at any location were the cured coating is present by the methods described elsewhere herein. A preferred (but non-limiting) device for forming indicia on or in the developable transparent cured or dyed microscope slide coverslip media described above is a semiconductor-type laser. These lasers are used in computer CD-ROM and CD-RAM readers and writers. Other lasers mentioned in this application or known in the art can also be used to form an indicia onto or into the developable transparent “cured” or ‘dyed” microscope slide coverslip media. Other lasers, for example, like the semiconductor lasers used in LightScribe® or LabelFlash® CD-ROM and CD-RAM computer components can be used with the present invention to develop the developable liquid microscope slide coverslip media once the microscope slide coverslip media coating is cured as described herein.

In another embodiment, the present invention is directed to a microscope slide and coverslip assembly comprising a microscope slide having a barcode thereon and having a microscope slide coverslip as defined herein adhered thereto.

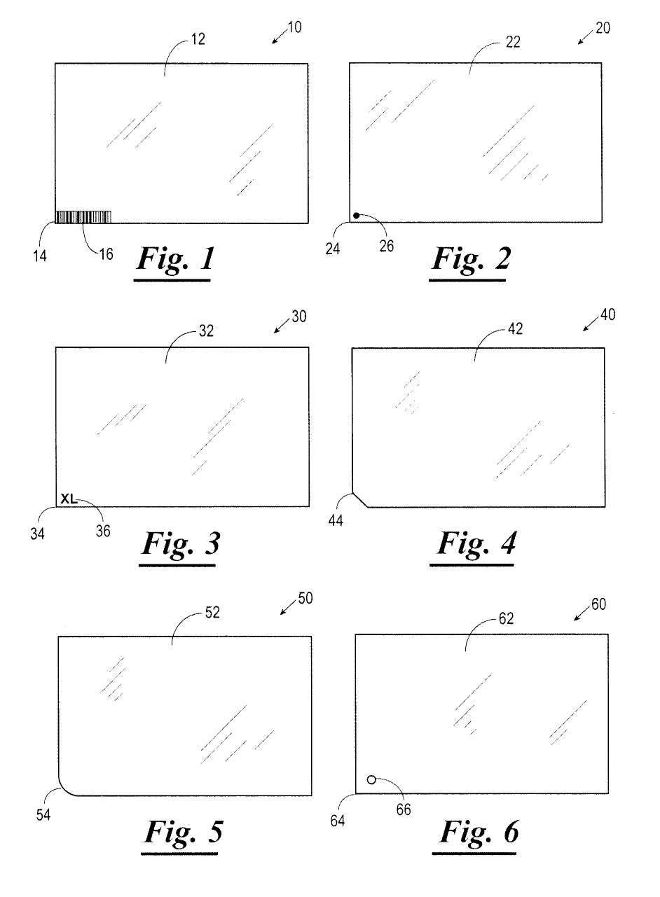

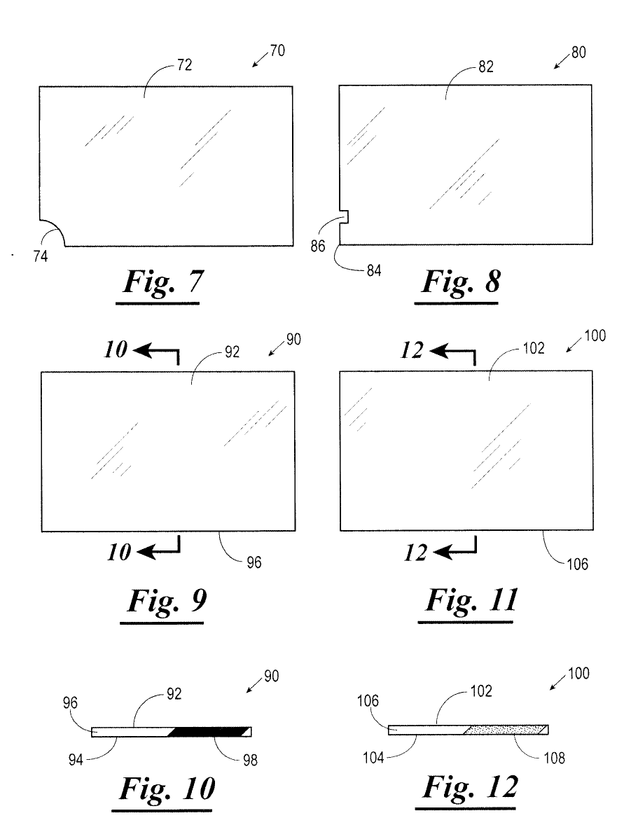

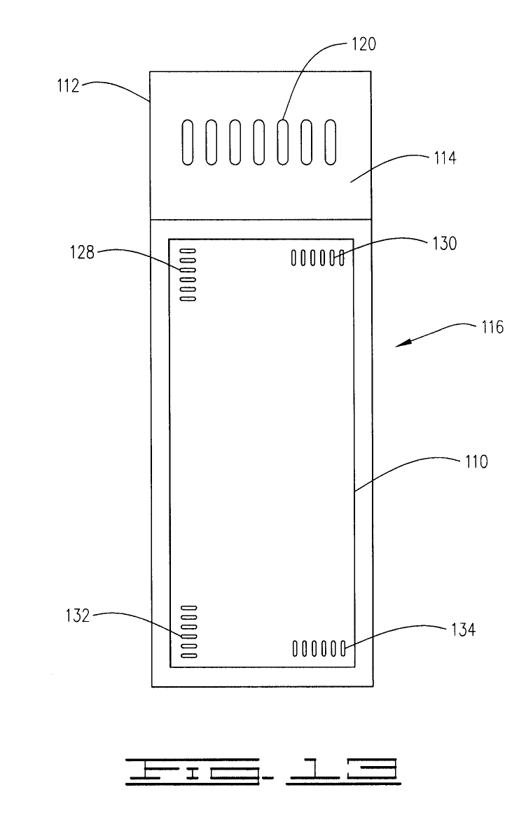

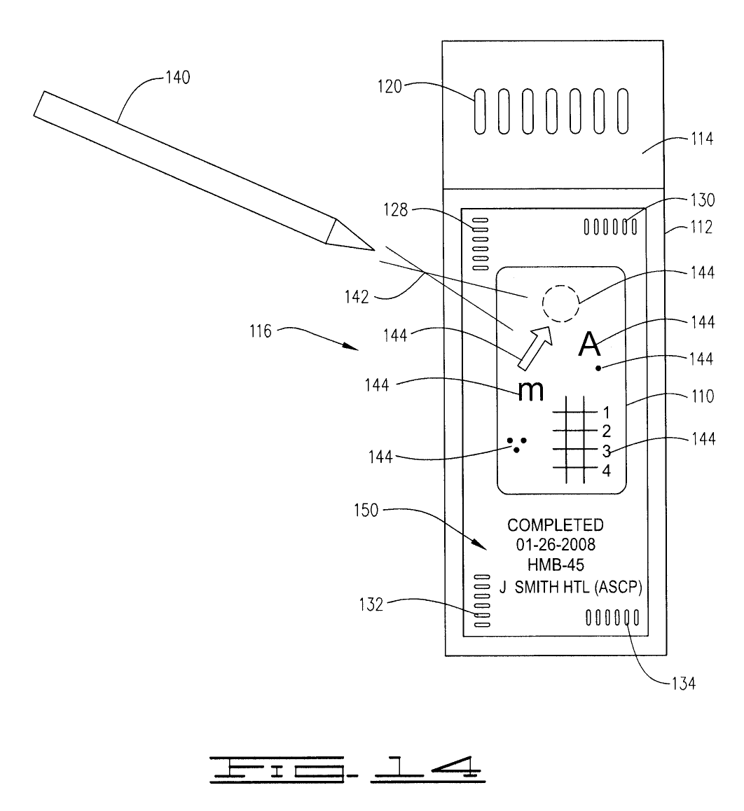

Turning now to the figures, shown therein are embodiments of the microscope slide coverslips of the present invention showing various indicia which may be used. Shown in FIG. 1 is a microscope slide coverslip 10 constructed of a glass or plastic plate as described elsewhere herein. Microscope slide coverslip 10 has an upper surface 12 and a corner 14. The microscope slide coverslip 10 has a barcode indicium 16 in the corner 14. The barcode 16 may be any barcode as contemplated or described herein. Shown in FIG. 2 is another microscope slide coverslip embodiment comprising microscope slide coverslip 20 with upper surface 22, corner 24 and indicium 26. Indicium 26 may comprise a printed dot, an etched dot, or a depression and may be colored, or have any shape other than a dot or circle. Shown in FIG. 3 is a microscope slide coverslip 30 having an upper surface 32, a corner 34 and an indicium 36 which in this case is an alphabetic and/or numeric symbol, such as letters. Shown in FIG. 4 is a microscope slide coverslip 40 having and upper surface 42. In this embodiment of the invention, the microscope slide coverslip 40 has an indicium 44 which comprises a corner truncated to have an angular edge which is distinguishable from all other corners of the microscope slide coverslip 40. FIG. 5 is a microscope slide coverslip 50 having an upper surface 52 and an indicium 54 which is a convex curved corner. FIG. 6 is a microscope slide coverslip 60 having an upper surface 62, a corner 64, and an indicium 66 which comprises a hole or depression in the microscope slide coverslip 60. FIG. 7 is a microscope slide coverslip 70 having an upper surface 72 and an indicium 74 which comprises an inwardly curved (concave) notch in a corner of the microscope slide coverslip 70. FIG. 8 is a microscope slide coverslip 80 having an upper surface 82, a corner 84 and an indicium 86 which comprises a notch in an edge in the microscope slide coverslip 80 near the corner 84. FIGS. 9 and 10 show a microscope slide coverslip 90 having an upper surface 92, a lower surface 94, and edge 96 and an indicium 98. The indicium 98 is a color (such as, but not limited to, white, black, red, blue, green, orange, or yellow) applied to at least a portion of edge 96. FIGS. 11 and 12 show a microscope slide coverslip 100 having an upper surface 102, a lower surface 104, an edge 106 and an indicium 108 which comprises an abraded or frosted surface of the edge 106.

In the embodiment of FIGS. 9 and 10 the indicium 98 may be color coded so the color of the microscope slide coverslip 90 indicates whether the microscope slide coverslip 90 is to be activated by an organic solvent versus an aqueous solvent. Further, the color of the indicium 98 may be such that the intensity of the color is accentuated when a plurality of the microscope slide coverslips 90 are stacked together.

FIG. 13 shows an embodiment of a microscope slide coverslip of the present invention designated by the reference numeral 110. Microscope slide coverslip 110 is disposed and preferably secured upon a microscope slide 112 on an upper surface 114 thereof to form a microscope slide-microscope slide coverslip assembly 116 (also referred to herein as a microscope slide-coverslip assembly). The microscope slide 110 has a primary indicium 120 thereon, which in the embodiment of FIG. 13 is an optical character recognition code (OCR) such as a barcode. The microscope slide coverslip 110 is represented as having four secondary indicia thereon, represented thereon as codes 128, 130, 132, and 134. Code 128 may be for example a “sign out” code as discussed above. Code 130 may be for example a “technician” code which is unique to a particular technician in the LIS. Code 132 may be for example a “type of test” code which represents the type of test used to evaluate a biological specimen of microscope slide 112. Code 134 may be for example a “finished test” code which indicates that the testing and/or evaluation of the biological specimen on the microscope slide has been completed. Codes 128, 130, 132, and 134 may be used interchangeably. More or fewer than four indicia may be positioned on the microscope slide coverslip 110, for example the microscope slide coverslip 110 may have one, two or three indicia, or five or more indicia thereon, for example 5, 6, 7, 8, 9, 10, 11, or 12, or more.

The code may indicate a processing step or other information regarding the microscope slide 112, for example it may involve a date, a test, a procedure, an end of testing of the microscope slide, a sign out of the microscope slide, a reporting of the microscope slide, a reading or scanning of the microscope slide, a name of or identification code assigned to a technician, physician assistant, physician, medical technologist, nurse, or medical professional who is assigned to or involved with the microscope slide for some purpose, a result of a test performed on the microscope slide, a decision regarding the microscope slide, a phrase assigned to the microscope slide, specifics or parameters regarding a test performed on the microscope slide, a code assigned to the microscope slide, an identity of the patient from whom the biological sample was obtained, or a combination of any thereof.

FIG. 14 shows an embodiment of the microscope slide-microscope slide coverslip assembly 116 of the invention wherein the microscope slide coverslip 110 is shown applied to the upper surface 114 of the microscope slide 112. Microscope slide coverslip 110 has a developable layer on an upper surface or lower surface of the microscope slide coverslip 110 as explained previously. A lightwave marking device 140 (for example a laser) may be used to apply a light wave 142 to the microscope slide coverslip 110 which activates a portion of the developable layer of the microscope slide coverslip 110 to form one or more markings 144 thereon as discussed above in regard to microscope slide coverslips which have developable (activatable) coatings. Additionally, slide-specific information 150 has been printed in the developable layer via a device, such as a laser-capable or illumination-capable PDA as discussed previously in regard to FIG. 14.

As noted above, the microscope slide coverslip 110 and microscope slide 112 may have one or more information-containing symbols (indicia) thereon. As shown in FIG. 14, the slide 112 may have primary symbol 120 which encodes the slide-specific information 150 which has been printed on the microscope slide coverslip 110. Further, as explained above, the microscope slide coverslip 110 may have additional information-containing codes such as indicia 128, 130, 132 and 134. These indicia may be readable via the same code-reading device able to read the primary indicium 120. For example, a laser-illuminating PDA could “read” any or all of the information-containing indicia 120, 128, 130, 132 and 134, and could electronically link and cross-index these indicia and the information contained therein in the LIS database discussed elsewhere herein. The slide-specific information 150 printed on the microscope slide coverslip 110 could thus be any or all of the information coded within the indicia 120, and 128-134.

The dry adhesive film microscope slide coverslips of the present invention can be used manually or in an automated microscope slide coverslipping instrument. Automated microscope slide coverslipping instruments known in the art can be easily modified by replacing the mountant normally dispensed onto the microscope slide with the solvent that activates the dry adhesive film, thus eliminating the inconsistencies of the mountant being dispensed onto the microscope slide prior to the placement of a prior art microscope slide coverslip. For example, there are several known inconsistencies when dispensing mountants in an automated microscope slide coverslipper. One major inconsistency is maintaining the viscosity of the mountant, which changes from day to day due to evaporation of the solvent over time wherein the mountant becomes more viscous. This increase in viscosity of the mountant causes the dispensing ports of automated microscope slide coverslippers to become clogged and subsequently inconsistent in the dispensing of the mountant onto the microscope slide. If the solvent is dispensed only onto the microscope slide or onto the adherent side of the microscope slide coverslip of the present invention, there is not a viscosity problem because any excessive solvent will evaporate and each activated adhesive microscope slide coverslip will have the same consistent layer of adhesive to cover and seal the biological specimen on the microscope slide.

In another embodiment, the invention is a self-adhering microscope slide coverslip constructed from an acrylic material which is solubilizable with organic solvents such as xylene. The acrylic material may be, for example, ethyl methacrylate or methyl methacrylate. In such an embodiment, the microscope slide coverslip is constructed without glass or without an additional plastic layer. The self-adhering microscope slide coverslip is exposed to an activating solvent and is then applied to a microscope slide and mounted thereon.

In this embodiment the microscope slide coverslip can be manufactured entirely from one or more of a polymer such as, but not limited to, ethyl methacrylate/methyl methacrylate copolymer, ethyl methacrylate, methyl methacrylate, butyl methacrylate, isobutyl methacrylate, acrylic ester copolymers, cyanoacrylates, ethyl acrylate, butyl acrylate, ethyl acetate, vinyl acrylates, aklyd bases acrylates, water bases acrylates, polyethylene, and epoxy resin polymers. Types of aqueous based polymers include AquaPerm™, commercially available from Thermo Electron Corp, and polyvinylacetate. This embodiment would feature a microscope slide coverslip having the chemical make up of polymers including up to 100% of the material of the microscope slide coverslip which, in use, becomes soft and sticky on the lower side contracting the solvent. Once in contact with the solvent, the lower portion of the polymer microscope slide coverslip becomes soft and tacky and seals the biological specimen and dries to a hard polymer film over the biological specimen. In the mechanism of activation, the solvent softens the hard polymer microscope slide coverslip lower surface and softens the microscope slide coverslip before the solvent evaporates. Once the solvent evaporates the lower softened slide of the microscope slide coverslip becomes hard again. This embodiment doesn't rely on the adhesive having a substrate (glass or plastic), but rather the entire microscope slide coverslip is a solubilizable microscope slide coverslip made from up to 100% soluble polymers. Either side of the microscope slide coverslip can be utilized to seal the biological specimen because the entire microscope slide coverslip is manufactured from the soluble polymer. In this embodiment only one side of the polymer microscope slide coverslip is softened by the solvent, while the top side remains hard. The softened side, once it re-hardens, remains transparent so the now sealed biological specimen can be viewed under a microscope.

While the invention has been described herein in connection with certain embodiments so that aspects thereof may be more fully understood and appreciated, it is not intended that the invention be limited to these particular embodiments. On the contrary, it is intended that all alternatives, modifications and equivalents are included within the scope of the invention as defined in the present claims. Thus the examples described herein, which include preferred embodiments, will serve to illustrate the practice of this invention, it being understood that the particulars shown are by way of example and for purposes of illustrative discussion of preferred embodiments of the present invention only and are presented in the cause of providing what is believed to be the most useful and readily understood description of procedures as well as of the principles and conceptual aspects of the invention. Changes may be made in the construction of the various embodiments described herein or in the steps or the sequence of steps of the methods described herein without departing from the spirit and scope of the invention as described and claimed herein.

Each of U.S. Ser. Nos. 11/585,448; 11/895,544; 11/895,501; 60/730,285; 60/738,872; and 60/771,546 and other patents, publications or references are expressly incorporated by reference herein in its entirety.

What is claimed is:

1. A microscope slide testing and identification assembly, comprising:
a microscope slide having at least one primary indicium thereon, and a biological sample disposed upon an upper surface of the microscope slide wherein the biological sample has been subjected to a treatment step, and wherein the at least one primary indicium represents primary information regarding the biological sample on the microscope slide; and
a microscope slide coverslip having at least one secondary indicium thereon, the microscope slide coverslip secured to the upper surface of the microscope slide in a position over the biological sample.

2. The assembly of claim 1 wherein the at least one secondary indicium represents secondary information in relation to the microscope slide.

3. The assembly of claim 1 wherein the primary information comprises an identity of the patient from which the biological sample was obtained or is a unique code which is assigned to said patient.

4. The assembly of claim 2 wherein the secondary information involves a processing step implemented in relation to the microscope slide and which further involves a date, a test, a procedure, an end of testing of the microscope slide, a sign out of the microscope slide, a reporting of the microscope slide, a reading or scanning of the microscope slide, a name of or identification code assigned to a technician, physician assistant, physician, medical technologist, nurse, or medical professional who is assigned to or involved with the microscope slide for some purpose, a result of a test performed on the microscope slide, a decision regarding the microscope slide, a phrase assigned to the microscope slide, specifics or parameters regarding a test performed on the microscope slide, a code assigned to the microscope slide, an identity of the patient from whom the biological sample was obtained, or a combination of any thereof.

5. The assembly of claim 1 wherein the microscope slide coverslip comprises:
a glass or plastic plate having a first surface, a second surface, and an outer peripheral edge, the first surface having an adhesive coating disposed thereon forming an adherent side and the second surface absent an adhesive coating forming a non-adherent side, and wherein prior to being secured to the microscope slide the adherent side has a dry, non-tacky condition until activated by a solvent to form a tacky condition.

6. The assembly of claim 5 wherein the at least one secondary indicium of the microscope slide coverslip is on or in the first surface, second surface, or outer peripheral edge thereof distinguishes the adherent side from the non-adherent side of the glass or plastic plate.

7. The assembly of claim 5 wherein the at least one secondary indicium is positioned on the non-adherent side of the glass or plastic plate.

8. The assembly of claim 5 wherein the at least one secondary indicium is positioned on the adherent side of the glass or plastic plate.

9. The assembly of claim 1 wherein the microscope slide coverslip is absent a dry adhesive coating thereon.

10. The assembly of claim 1 wherein the at least one secondary indicium of the microscope slide coverslip is at least one of a dot, circle, mark, code, barcode, label, character, shape, symbol, letter, number, line, insignia, pattern, color, holographic image, or iridescent image or a combination thereof.

11. The assembly of claim 1 wherein the at least one secondary indicium is a notch, hole, depression, truncated corner, nick, etching, incision, laterally-extending protuberance, physical alteration of the microscope slide coverslip, or combination thereof.

12. The assembly of claim 1 wherein the at least one secondary indicium of the microscope slide coverslip is a truncated corner thereof.

13. The assembly of claim 1 wherein the at least one primary indicium and the at least one secondary indicium each is machine readable.

14. The assembly of claim 1 wherein the at least one secondary indicium is unique.

15. The assembly of claim 1 wherein the at least one secondary indicium is positioned asymmetrically on the microscope slide coverslip.

16. The assembly of claim 1 wherein the at least one secondary indicium is on an upper surface thereof.

17. The assembly of claim 1 wherein the at least one secondary indicium is on a lower surface thereof.

18. The assembly of claim 1 wherein the at least one secondary indicium has a height of 0.1 inch or less.

19. The assembly of claim 1 wherein the at least one secondary indicium is operationally associated with the at least one primary indicium in an information processing system or database.

20. The assembly of claim 1 wherein the microscope slide coverslip is a self-adhering microscope slide coverslip constructed of a solubilizable transparent polymeric material which is solubilizable via an aqueous solvent or organic solvent.

21. The assembly of claim 1 wherein the microscope slide coverslip is constructed of a glass or plastic material.

22. The assembly of claim 1 wherein the microscope slide coverslip comprises means for adding an additional secondary indicium thereto before or after the microscope slide coverslip has been secured to the microscope slide.

23. The assembly of claim 1 wherein the microscope slide comprises means for adding an additional primary indicium thereto before or after the microscope slide coverslip is secured to the microscope slide.

24. A method of processing a microscope slide, comprising:
providing a microscope slide assembly comprising a microscope slide and a microscope slide coverslip disposed thereon, the microscope slide having at least one primary indicium thereon, and having a biological sample disposed on an upper surface of the microscope slide, wherein the biological sample has been subjected to a treatment step, and wherein the at least one primary indicium on the microscope slide represents primary information which is associated with the biological sample on the microscope slide, and wherein the microscope slide coverslip is secured to the upper surface of the microscope slide in a position over the biological sample, and wherein the microscope slide coverslip has at least one secondary indicium thereon;
electronically recording the at least one secondary indicium of the microscope slide coverslip; and
electronically associating secondary information with the electronically recorded at least one secondary indicium of the microscope slide coverslip.

25. The method of claim 24 wherein the secondary information represents a processing step implemented in relation to the microscope slide.

26. The method of claim 24 wherein the at least one secondary indicium is recorded electronically into an electronic laboratory information system.

27. The method of claim 24 wherein the primary information is an identity of the patient from which the biological sample was obtained or is a unique code which is assigned to said patient.

28. The method of claim 25 wherein the processing step implemented in relation to the microscope slide involves a date, a test, a procedure, an end of testing of the microscope slide, a sign out of the microscope slide, a reporting of the microscope slide, a reading or scanning of the microscope slide, a name of or identification code assigned to a technician, physician assistant, physician, medical technologist, nurse, or medical professional who is assigned to or involved with the microscope slide for some purpose, a result of a test preformed on the microscope slide, a decision regarding the microscope slide, a phrase assigned to the microscope slide, specifics or parameters regarding a test performed on the microscope slide, a code assigned to the microscope slide, an identity of the patient from whom the biological sample was obtained, or a combination of any thereof.

29. A method of processing a microscope slide disposed on a microscope, comprising:
providing a microscope slide assembly comprising a microscope slide and a microscope slide coverslip disposed thereon, the microscope slide having at least one primary indicium thereon, and having a biological sample disposed on an upper surface of the microscope slide, wherein the biological sample has been subjected to a treatment step, and wherein the at least one primary indicium on the microscope slide represents primary information which is associated with the biological sample on the microscope slide, and wherein the microscope slide coverslip is secured to the upper surface of the microscope slide in a position over the biological sample, and wherein at least one of the microscope slide and the microscope slide coverslip has a coating which is developable by photoactivation and is transparent or invisible and wherein when at least a portion of the coating is exposed to a photoactivating wavelength, the exposed portion is formed into a mark thereon which is distinguishable from unexposed portion of the coating;
disposing the microscope slide assembly on the microscope; and
exposing the microscope slide and/or the microscope slide coverslip to the photoactivating wavelength such that the mark is formed in the exposed portion of the coating, wherein the mark is formed on a portion of the microscope slide coverslip or on a portion of the microscope slide immediately beneath the microscope slide coverslip, and wherein the photoactivating wavelength is provided through a lens or objective of the microscope upon which the microscope slide is disposed.

30. The method of claim 29 wherein the microscope slide coverslip of the microscope slide assembly has a secondary indicium having secondary information assigned thereto.

31. The method of claim 29 wherein the mark is formed in the microscope slide coverslip in a position directly above or adjacent a portion of the biological specimen disposed underneath the microscope slide coverslip.
